(19) United States
(12) Patent Application Publication
(10) Pub. No.: US 2007/0284732 A1
(43) Pub. Date: Dec. 13, 2007

(54) Semiconductor device, heat dissipating unit, and method for making a heat dissipating unit

(75) Inventors: Tzung-Lin Huang, Kaohsiung City (TW); Tsung-Kun Lee, Feng-Shan City (TW); Chun-Hsien Huang, Kaohsiung City (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sunup Technology Co., Ltd., K.E.P.Z. (TW)

(21) Appl. No.: 11/449,907

(22) Filed: Jun. 8, 2006

(51) Int. Cl. H01L 23/34

(52) U.S. Cl. 257/712

(57) ABSTRACT

A heat dissipating unit includes a hat-shaped body of a metal layered structure having: a copper alloy layer having upper and lower surfaces; a nickel layer formed on the upper surface of the copper alloy layer; a chrome layer formed on the nickel layer; and a metal oxide layer formed on the lower surface of the copper alloy layer. A semiconductor device includes: a substrate; a semiconductor chip mounted on the substrate; and a hat-shaped body of a metal layered structure mounted on the substrate and defining an inner space to receive the semiconductor chip therein.

### BACKGROUND OF THE INVENTION

1. Field of the Invention

This invention relates to a heat dissipating unit adapted to dissipate heat generated by a semiconductor chip mounted on a substrate, and a method for making the same. This invention also relates to a semiconductor device including the heat dissipating unit.

2. Description of the Related Art

FIG. 1 shows a conventional heat dissipating unit 2 that includes: a metal layered structure having a copper alloy layer 21 with upper and lower surfaces 212, 211; a nickel layer 23 formed on the upper surface 212 of the copper alloy layer 21; and a metal oxide layer 24 formed on the lower surface 211 of the copper alloy layer 21.

The metal layered structure includes a first portion 20 and a second portion 20′ extending from the first portion 20 and attached to a substrate 12. The first portion 20 of the metal layered structure cooperates with the substrate 12 to define an inner space for receiving a semiconductor chip 11 therein. A central portion of the first portion 20 of the metal layered structure is indented so as to contact the semiconductor chip 11. The heat dissipating unit 2 further includes a plurality of through-holes 25 for filling an encapsulant (not shown) into the inner space to enclose the semiconductor chip 11.

As shown in FIG. 2, the conventional heat dissipating unit 2 is made by: cleaning and washing the copper alloy layer 21 so as to remove impurities and rust therefrom; forming the nickel layer 23 on the copper alloy layer 21 through electroplating techniques so as to form a layered structure; cleaning and drying the copper alloy layer 21; press forming the layered structure; and immersing the copper alloy layer 21 in an oxidation solution so as to form a copper oxide layer 24 on the copper alloy layer 21 opposite to the nickel layer 23.

The nickel layer 23 not only prevents the copper alloy layer 21 from oxidization, but also improves the appearance thereof. In addition, the black copper oxide layer 24 facilitates even distribution of the encapsulant in the inner space in the metal layered structure, and enhances heat absorption from the semiconductor chip 11.

In spite of the anti-oxidation (i.e., anti-rust) property of the nickel layer 23, rust can still occur at the nickel layer 23. Additionally, high temperature of the semiconductor chip 11 during operation is disadvantageous to anti-oxidation, thereby resulting in an increase in rust formation. Hence, it is insufficient for a heat dissipating unit to merely use a nickel layer as an anti-oxidation layer.

### SUMMARY OF THE INVENTION

Therefore, an object of the present invention is to provide a heat dissipating unit that can overcome the aforesaid drawback of the prior art, and a method for making the same.

Another object of the present invention is to provide a semiconductor device including the heat dissipating unit with superior anti-oxidation property.

According to one aspect of the present invention, a heat dissipating unit is adapted to dissipate heat generated by a semiconductor chip mounted on a substrate, and comprises a hat-shaped body of a metal layered structure including: a copper alloy layer having upper and lower surfaces; a nickel layer formed on the upper surface of the copper alloy layer; a chrome layer formed on the nickel layer; and a metal oxide layer formed on the lower surface of the copper alloy layer.

According to another aspect of the present invention, a semiconductor device comprises: a substrate; a semiconductor chip mounted on the substrate; and a hat-shaped body of a metal layered structure mounted on the substrate and defining an inner space to receive the semiconductor chip therein. The hat-shaped body of the metal layered structure includes: a copper alloy layer having upper and lower surfaces, a nickel layer formed on the upper surface of the copper alloy layer, a chrome layer formed on the nickel layer, and a metal oxide layer formed on the lower surface of the copper alloy layer.

According to yet aspect of the present invention, a method for making a heat dissipating unit adapted to dissipate heat generated by a semiconductor chip mounted on a substrate comprises the steps of: providing a metal plate of a copper alloy having an upper surface and a lower surface; forming a nickel layer on the upper surface of the metal plate; forming a chrome layer on the nickel layer such that a layered structure is provided; shaping the layered structure into a hat-shaped body with a plurality of through-holes; and forming a metal oxide layer on the lower surface of the metal plate of the shaped layered structure.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a fragmentary cross-sectional view of a conventional heat dissipating unit;

FIG. 2 is a flow chart illustrating consecutive steps of a conventional method for making the conventional heat dissipating unit shown in FIG. 1;

FIG. 3 is a fragmentary cross-sectional view of the preferred embodiment of a heat dissipating unit according to this invention;

FIG. 4 is a perspective view of the preferred embodiment;

FIG. 5 is a fragmentary cross-sectional view of the preferred embodiment of a semiconductor device according to this invention; and

FIGS. 6 to 14 are schematic views to illustrate consecutive steps of the preferred embodiment of a method for making the heat dissipating unit shown in FIG. 3.

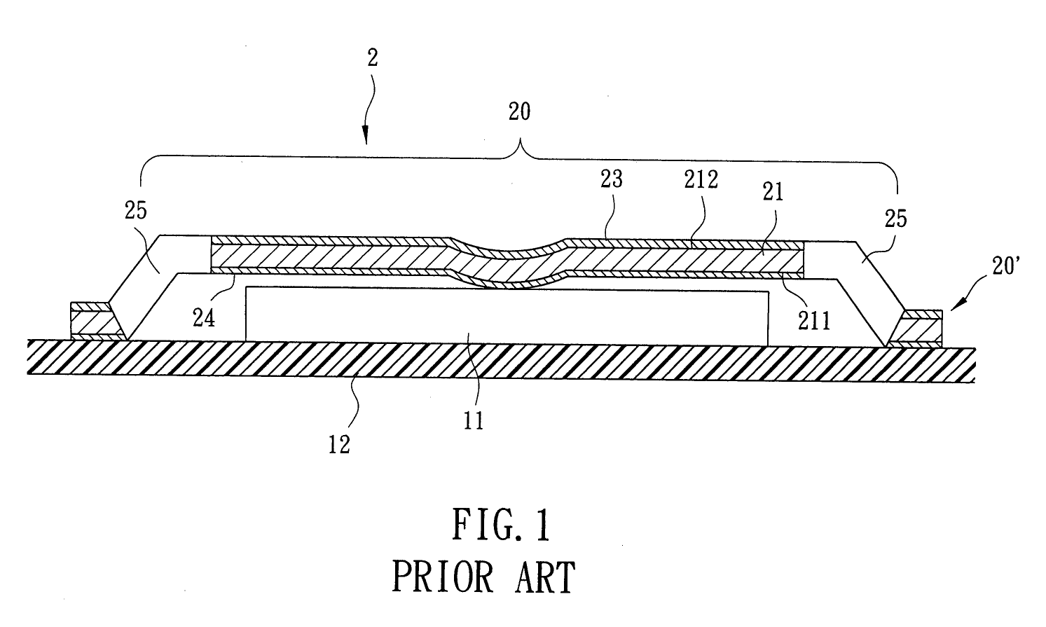

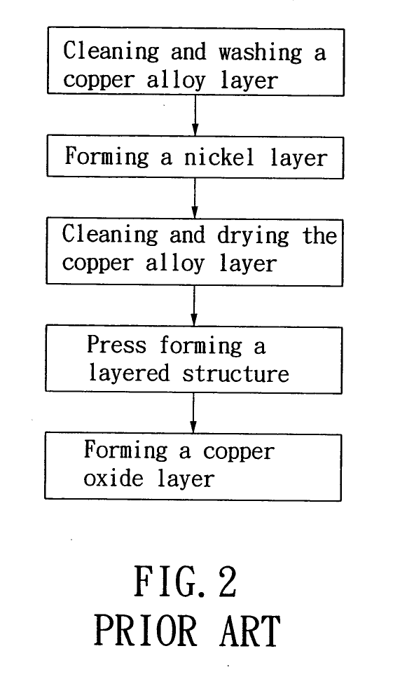

### DETAILED DESCRIPTION OF THE PREFERRED EMBODIMENT

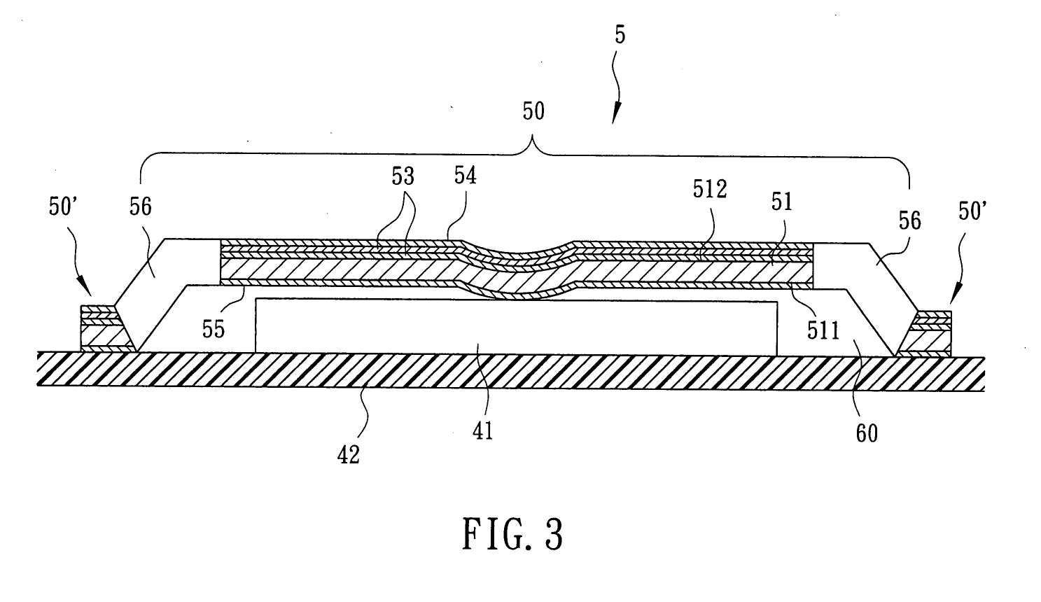

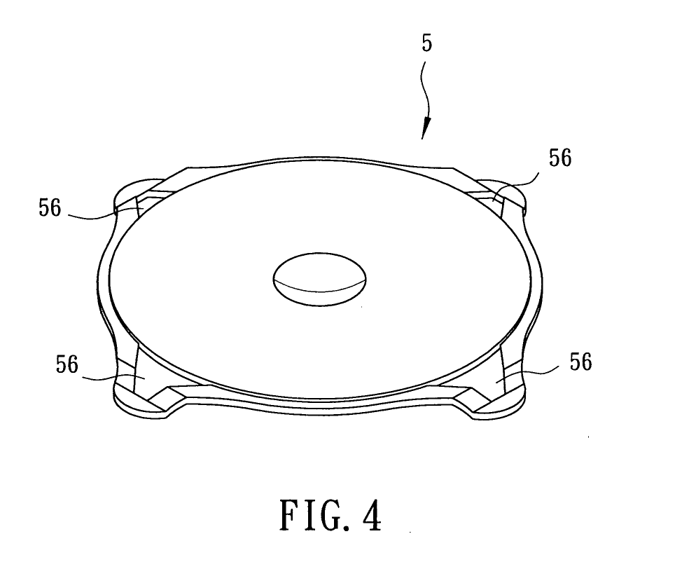

FIGS. 3 and 4 illustrate the preferred embodiment of a heat dissipating unit according to the present invention. The heat dissipating unit includes a hat-shaped body 5 of a metal layered structure having: a copper alloy layer 51 having upper and lower surfaces 512, 511; two nickel layers 53 formed on the upper surface 512 of the copper alloy layer 51; a chrome layer 54 formed on the nickel layers 53; and a metal oxide layer 55 formed on the lower surface 511 of the copper alloy layer 51.

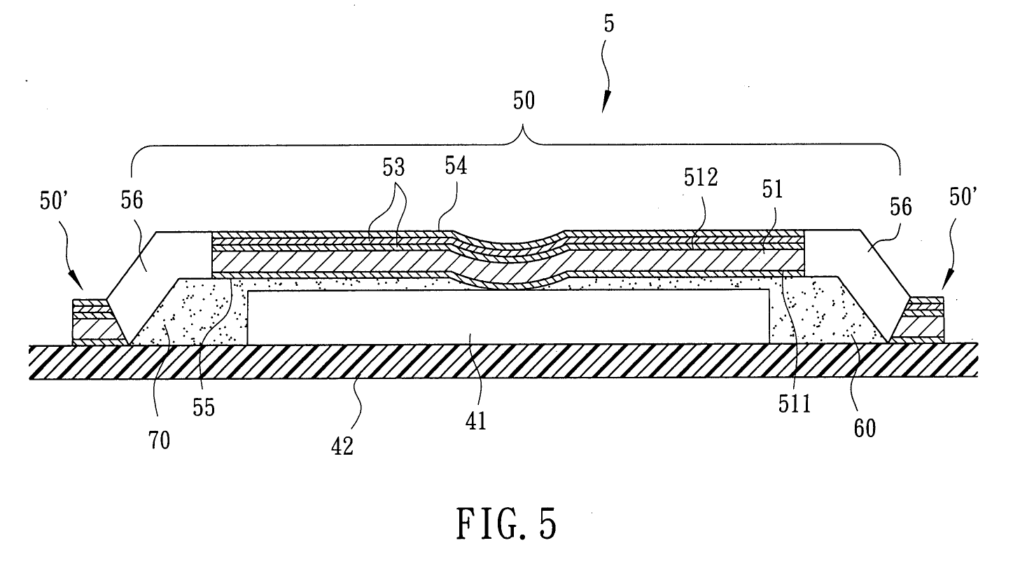

In this embodiment, the hat-shaped body 5 of the metal layered structure defines an inner space 60 adapted to receive a semiconductor chip 41 therein, and is adapted to be mounted on a substrate 42. Preferably, the hat-shaped body 5 includes a crown portion 50 that defines the inner space 60, and a brim portion 50′ that is mounted on the substrate 42 and that is disposed around the crown portion 50. The crown portion 50 is formed with a plurality of through-holes 56 adapted for filling an encapsulant (see FIG. 5) into the inner space 60 so as to enclose the semiconductor chip 41.

FIG. 5 illustrates the preferred embodiment of a semiconductor device according to this invention which utilizes the heat dissipating unit shown in FIG. 3. In this embodiment, an encapsulant 70 is injected into the inner space 60 through the through-holes 56 in the crown portion 50 of the hat-shaped body 5 of the metal layered structure such that the semiconductor chip 41 mounted on the substrate 42 is enclosed by the encapsulant 70 in the inner space 60 defined by the heat dissipating unit 5.

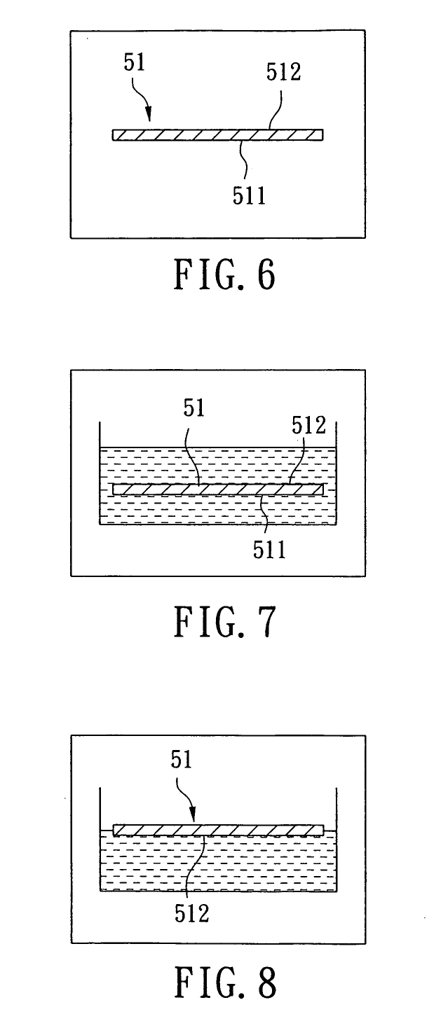

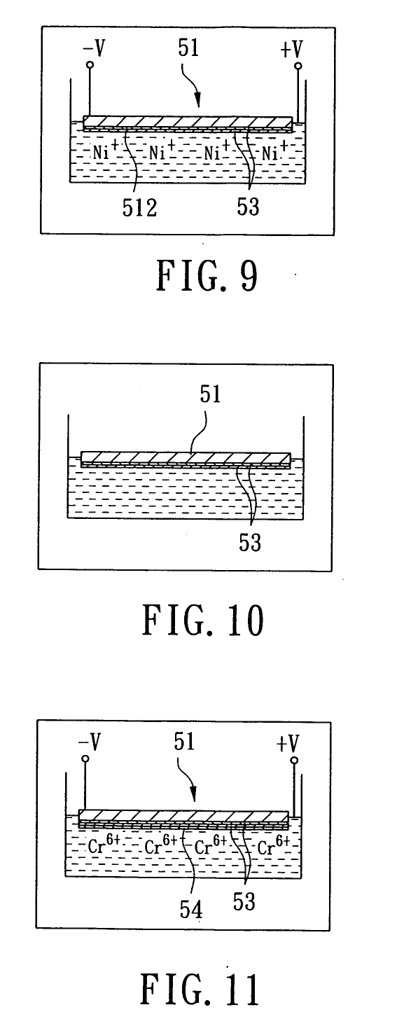

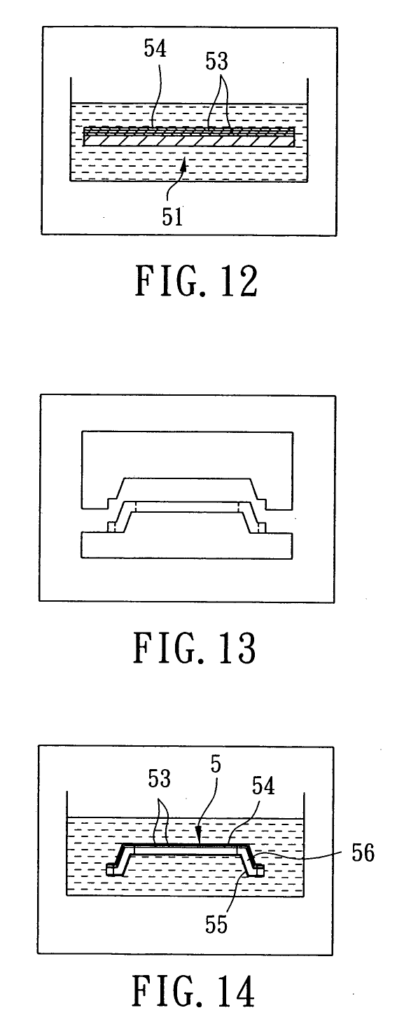

FIGS. 6 to 14 illustrate consecutive steps of the preferred embodiment of a method for making the heat dissipating unit shown in FIG. 3. The method includes the steps of: providing a metal plate 51 of a copper alloy having an upper surface 512 and a lower surface 511 (see FIG. 6); forming two nickel layers 53 on the upper surface 512 of the metal plate 51 (see FIG. 9); forming a chrome layer 54 on the nickel layer 53 such that a layered structure is provided (see FIG. 11); press-forming the layered structure into a hat-shaped body with a plurality of through-holes 56 (see FIG. 13); and forming a metal oxide layer 55 on the lower surface 511 of the metal plate 51 of the shaped layered structure (see FIG. 14).

In this embodiment, before forming the nickel layer 53, the metal plate 51 of the copper alloy is subjected to a cleaning process for removing grease, impurities, and rust from the metal plate 51. As shown in FIG. 7, the metal plate 51 is first immersed in an acidic or alkaline solution with or without heating to remove grease on the surfaces 512, 511 of the metal plate 51. Then, the metal plate 51 is subjected to an electrolytic degreasing process to remove residual impurity and grease on the metal plate 51. An ultrasonic device can be employed in the electrolytic degreasing process. As shown in FIG. 8, the upper surface 512 of the metal plate 51 is further subjected to an acid cleaning step, and is immersed in an acidic solution containing nitric acid and sulfuric acid to remove the rust through erosion (see FIG. 8), followed by washing with water to remove the acidic solution. It should be noted herein that the concentration of the acidic solution and treating time should be precisely controlled to prevent over-erosion of the metal plate 51. A suitable amount of an inhibitor can also be added into the acidic solution to prevent over-erosion.

In this embodiment, the step of forming the nickel layer 53 is conducted through electroplating techniques. That is, the upper surface 512 of the metal plate 51 of the copper alloy is immersed in a plating solution containing nickel ions (Ni⁺), followed by electrically connecting the metal plate 51 to a cathode and applying a current such that the nickel ions (Ni⁺) in the plating solution are gradually deposited on the upper surface 512 of the metal plate.51 so as to form the nickel layer 53 (see FIG. 9). The deposition rate and the thickness of the nickel layer 53 can be controlled by adjusting the concentration of the plating solution, the magnitude of current, or temperature of the plating solution. The step can be repeated more than once so as to form multiple nickel layers. Alternatively, electroless plating techniques can be employed instead of electroplating techniques, in which nickel layer is coated on the metal plate 51 of the copper alloy through chemical reduction reaction in the presence of a catalyst. The electroless plating techniques is understood by a skilled artisan and will not be further described hereinafter.

During formation of the nickel layer 53, a finishing agent or a fogging agent can be added into the plating solution so as to alter the surface appearance of the nickel layer 53. After electroplating, the residual electroplating solution was removed by washing with a neutral solution, such as water.

Preferably, before forming the chrome layer 54, the nickel layer 53 on the metal plate 51 is subjected to another acid cleaning step to remove rust on the nickel layer 53 (see FIG. 10).

The step of forming the chrome layer 54 is conducted through electroplating techniques. The nickel layer 53 is immersed in a chrome ion (Cr⁶⁺)-containing electroplating solution, followed by electrically connecting the metal plate 51 of the copper alloy to a cathode and applying a current such that chrome ions (Cr⁶⁺) in the electroplating solution are gradually deposited on the nickel layer 53 (see FIG. 11). In general, a thickness of about tens of nanometers for the chrome layer 54 is sufficient to provide a desired rigidity and anti-oxidation property. Moreover, because the chrome layer 54 is relatively thin, any pattern appearing on the nickel layer 53 will be visible through the chrome layer 54.

After depositing the chrome layer 54 on the nickel layer 53, the layered structure is immersed in or rinsed with a neutral solution, such as water, and then dried.

Preferably, the step of forming the metal oxide layer 55 is conducted by immersing the shaped layered structure into an oxidation solution (e.g., a high concentration alkaline solution having an oxidant) such that the metal plate 51 of the copper alloy is subjected to an oxidation reaction so as to form copper oxide on the lower surface 511 of the metal plate 51. Preferably, after the oxidation step, the product is washed with a neutral solution to remove the oxidation solution.

It should be noted herein that, since adhesion between chrome metal and nickel metal is superior to that between chrome metal and copper metal, the nickel layer 53 has to be deposited on the metal plate 51 of the copper alloy before depositing the chrome layer 54.

According to the present invention, since the chrome layer 54 is easily formed into an inert layer in the air, it enhances the protection of the heat dissipating unit from damage due to oxidation and corrosion.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A heat dissipating unit adapted to dissipate heat generated by a semiconductor chip mounted on a substrate, comprising a hat-shaped body of a metal layered structure including:
a copper alloy layer having upper and lower surfaces;
a first nickel layer formed on said upper surface of said copper alloy layer;
a chrome layer formed on said first nickel layer; and
a metal oxide layer formed on said lower surface of said copper alloy layer.

2. The heat dissipating unit of claim 1, wherein said hat-shaped body includes a crown portion that is formed with a plurality of through-holes.

3. The heat dissipating device of claim 1, further comprising a second nickel layer formed on said first nickel layer.

4. A semiconductor device comprising:
a substrate;
a semiconductor chip mounted on said substrate; and
a hat-shaped body of a metal layered structure mounted on said substrate and defining an inner space to receive said semiconductor chip therein;
wherein said metal layered structure includes:
a copper alloy layer having upper and lower surfaces,
a first nickel layer formed on said upper surface of said copper alloy layer,
a chrome layer formed on said first nickel layer, and
a metal oxide layer formed on said lower surface of said copper alloy layer.

5. The semiconductor device of claim 4, further comprising an encapsulant filling said inner space to enclose said semiconductor chip.

6. The semiconductor device of claim 5, wherein said hat-shaped body has a crown portion that defines said inner space, and a brim portion that is mounted on said substrate.

7. The semiconductor device of claim 4, further comprising a second nickel layer formed on said first nickel layer.

8. A method for making a heat dissipating unit adapted to dissipate heat generated by a semiconductor chip mounted on a substrate, comprising the steps of:
providing a metal plate of a copper alloy having an upper surface and a lower surface;
forming a nickel layer on the upper surface of the metal plate;
forming a chrome layer on the nickel layer such that a layered structure is provided;
shaping the layered structure into a hat-shaped body with a plurality of through-holes; and
forming a metal oxide layer on the lower surface of the metal plate of the shaped layered structure.

9. The method of claim 8, wherein the step of forming the nickel layer is conducted through electroplating.

10. The method of claim 8, wherein the step of forming the nickel layer is conducted through electroless plating.

11. The method of claim 8, wherein the step of forming the chrome layer is conducted through electroplating using a chrome ion-containing electroplating solution.

12. The method of claim 8, wherein the step of forming the metal oxide layer is conducted by immersing the metal plate of the shaped layered structure into an oxidation solution.

13. The method of claim 8, further comprising a cleaning step for removing grease, impurities, and rust on the metal plate before forming the nickel layer.

14. The method of claim 8, further comprising a cleaning step for removing rust on the nickel layer before forming the chrome layer.

15. The method of claim 11, further comprising a treating step for removing residual electroplating solution on the metal plate of the layered structure, and drying the metal plate of the layered structure before the shaping step.
